(19) United States
(12) Patent Application Publication
(10) Pub. No.: US 2003/0157438 A1
(43) Pub. Date: Aug. 21, 2003

(54) BUMP FORMING PROCESS

(76) Inventors: Ho-Ming Tong, Taipei (TW); Chun-Chi Lee, Kaohsiung (TW); Jen-Kuang Fang, Pingtung Hsien (TW); Min-Lung Huang, Kaohsiung (TW); Jau-Shoung Chen, Hsinchu Hsien (TW); Ching-Huei Su, Kaohsiung (TW); Chao-Fu Weng, Tainan (TW); Yung-Chi Lee, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,464

(22) Filed: Jan. 22, 2003

(30) Foreign Application Priority Data
Feb. 20, 2002 (TW) 91102870

(51) Int. Cl. G03F 7/20; C25F 3/00; B23H 3/00; H05K 3/07; B23H 5/00; B23H 7/00; B23K 35/12; G03F 7/40; C25F 7/00; B23H 9/00; B23H 11/00; H01L 21/00

(52) U.S. Cl. 430/314; 430/318; 205/667; 205/682; 228/246

(57) ABSTRACT

A process for forming a plurality of bumps on a wafer comprises forming a first UBM (under ball metallurgy) over an active surface of a wafer. A second UBM is formed over the first UBM. A part of the second UBM is removed to expose the first UBM. A plurality of solders are respectively formed to cover the second UBM and the first UBM not covered by the second UBM. The first UBM not covered by the second UBM and not covered by the solders is removed.

### CROSS REFERENCE TO RELATED APPLICATIONS

This application claims the priority benefit of Taiwan application serial no. 911 02870, filed Feb. 20, 2002.

### BACKGROUND OF INVENTION

1. Field of the Invention

The present invention relates to a bump forming process. More specifically, the present invention relates to a bump forming process which reduces the time that an etchant contacts a bump to control the bump volume, and needs a photoresist with a decreased thickness.

2. Description of the Related Art

Flip chip packaging technology is advantageous because it has high density contact points and short circuit path compared to a wire bonding process and tape automatical bonding (TAB). Furthermore, the flip chip package has especially high heat dissipation efficiency when the rear side of the chip is exposed.

FIG. 1 through FIG. 7 are cross-sectional views showing a conventional bump forming process. With reference to FIG. 1, a wafer 110 having an active surface 112 is provided. A passivation layer 114 and a plurality of bonding pads 116 (only one is shown) are formed on the active surface 112 of the wafer 110, the passivation layer 114 exposing the bonding pad 116.

With reference to FIG. 2, an adhesive layer 120 is formed on the active surface 112 of the wafer 110 by sputtering. The adhesive layer 120 covers the bonding pad 116 and the passivation layer 114. A barrier layer 130 is formed over the adhesive layer 120 by sputtering or plating. A wettable layer 140 is formed over the barrier layer 130 by sputtering or plating. Thereby is formed an under ball metallurgy (UBM) 142.

With reference to FIG. 3, a photoresist layer 150 is formed over the wettable layer 140 by a photolithography process. After exposure and development of the photoresist layer 150, the photoresist layer 150 is patterned to have a plurality of openings 152 which expose the wettable layer 140 on the bonding pad 116.

With reference to FIG. 4, a plurality of solders 160 are respectively formed in the openings 152 of the patterned photoresist layer 150, each of the solders 160 partially covering the wettable layer 140.

With reference to FIG. 4 and FIG. 5, the patterned photoresist layer 150 is removed from the wettable layer 140.

With reference to FIG. 5 and FIG. 6, the portion of the UBM 142 not covered by the solders 160 is removed by etching to expose the passivation layer 114.

With reference to FIG. 7, a flux can be optionally distributed over the solders 160 before the solders 160 are heated to help the solders 160 respectively melt into a ball shape. After cooling, a plurality of bumps 170 including the UBM 142 and the solders 160 are accomplished.

As shown, when the UBM 142 is to be etched after the solders 160 are formed in the openings 152, etchants are separately applied to the wettable layer 140, the barrier layer 130 and the adhesive layer 120. In each of the separate etching steps, a part of each solder 160 is removed and therefore the volume of the solder 160 is disadvantageously reduced. More particularly, in the case where an improper etchant for removing the wettable layer 140 and the barrier layer 130 is used, the solders 160 tend to peel from the wettable layer 140. Furthermore, the diameter of each the openings 152 is limited due to the area size of the UBM. For the solders 160 in the openings 152 to be high enough, the photoresist 150 must be sufficiently thick, which results in an increased production cost.

### SUMMARY OF THE INVENTION

It is one object of the invention to provide a bump forming process which reduces the contact time of an etchant with a bump to control the bump volume, and reduces the thickness of the formed photoresist.

It is another object of the invention to provide a bump forming process which can prevent a solder from peeling off due to an over-etching of the etchant.

Furthermore, it is another object of the invention to provide a bump forming process, in which a photoresist with a large opening is formed. The height of the solder can be reduced for a same volume of solder. Therefore, the thickness of the photoresist is reduced.

In order to achieve the above and other objectives, a process for forming a plurality of bumps on a wafer is provided. A passivation layer and a plurality of bonding pads are formed on an active surface of the wafer, the passivation layer exposing the bonding pads. An adhesive layer is formed on the active surface of the wafer to cover the bonding pads and the passivation layer. Subsequently, a barrier layer is formed over the adhesive layer and a wettable layer is formed over the barrier layer.

A first photolithography process is performed to form a patterned photoresist layer on the wettable layer. A first etching process is performed to remove the portions of the wettable layer and barrier layer not covered by the photoresist layer. Then, the photoresist layer is removed.

A second photolithography process is performed to form a photoresist layer having a plurality of openings respectively exposing the portions of the wettable layer and adhesive layer not covered by the barrier layer. A plurality of solders are respectively formed in the openings to cover the portions of the wettable layer and adhesive layer not covered by the barrier layer. The photoresist then is removed.

A second etching process is performed to respectively expose the portion of the adhesive layer not covered by the solders and the passivation layer of the wafer.

A first reflow process is performed to respectively shape the solder into balls. The balls are constricted on the wettable layer, and the portion of adhesive layer not covered by the barrier layer is exposed. A third etching process is performed to remove the exposed adhesive layer. Then, a second reflow process is performed.

The first reflow process, the third etching process and the second reflow process are optional. The material for the adhesive layer is, for example, titanium, titanium-tungsten alloy, aluminum or chromium. The material for the barrier layer is, for example, nickel-vanadium alloy. The material for the wettable layer can be copper, palladium or gold.

Etching the UMB is achieved by three steps. In the first etching step where the wettable layer and the barrier layer are etched, the solder is not formed on the wettable layer and therefore is not eroded by the etchant. In the second and third etching steps where the adhesive layer is etched, the etchant contacts and erodes the solder. The time during which the etchant contacts with the solder is increased, and the removed volume of the solder is thus minimized.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 through FIG. 7 are enlarged cross-sectional views showing a process for forming a bump on a wafer known in the prior art; and

FIG. 8 through FIG. 19 are enlarged cross-sectional views showing a process for forming a bump on a wafer according to one embodiment of the invention.

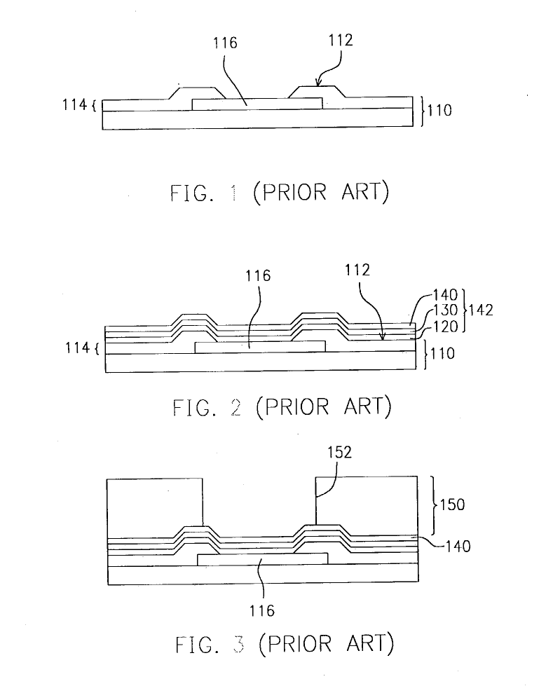

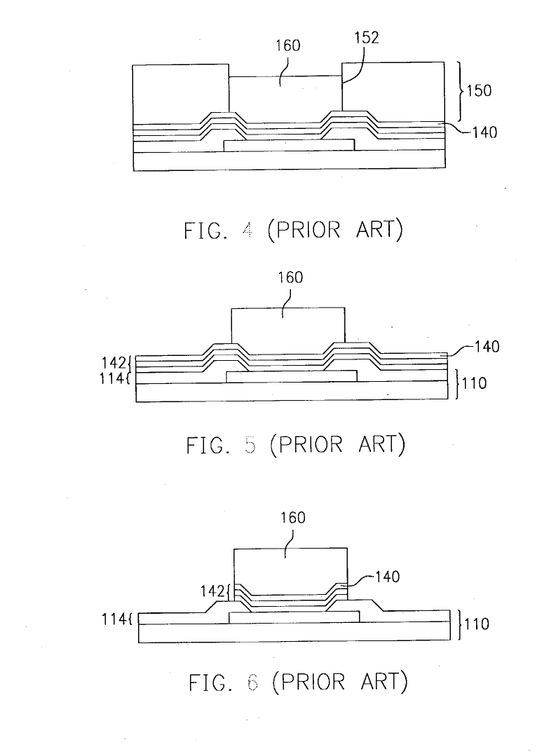

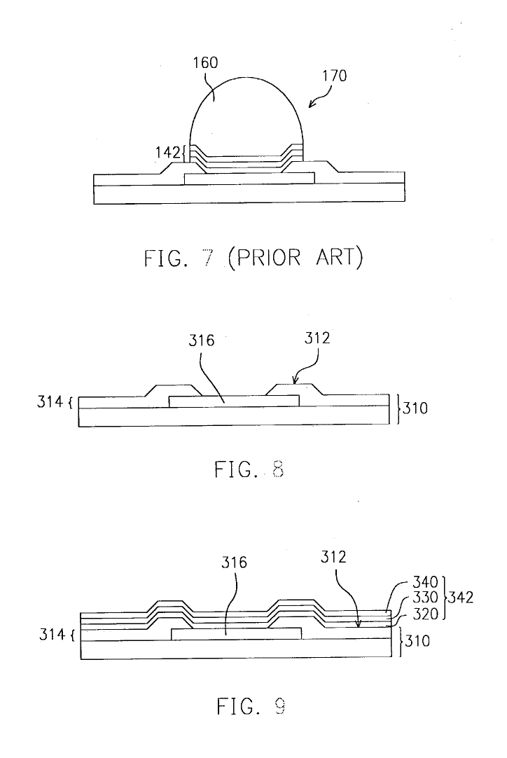

### DETAILED DESCRIPTION

Reference will now be made in detail to the present preferred embodiments of the invention, examples of which are illustrated in the accompanying drawings. Whenever possible, the same reference numbers are used in the drawings and the description to refer to the same or like parts.

FIG. 8 through FIG. 19 are enlarged cross-sectional views showing a process for forming a bump on a wafer according to one embodiment of the invention.

With reference to FIG. 8, a wafer 310 has an active surface 312. A passivation layer 314 and a plurality of bonding pads 316 (only one is shown) are formed on the active surface 312 of the wafer 310, the passivation layer 314 exposing the bonding pads 316.

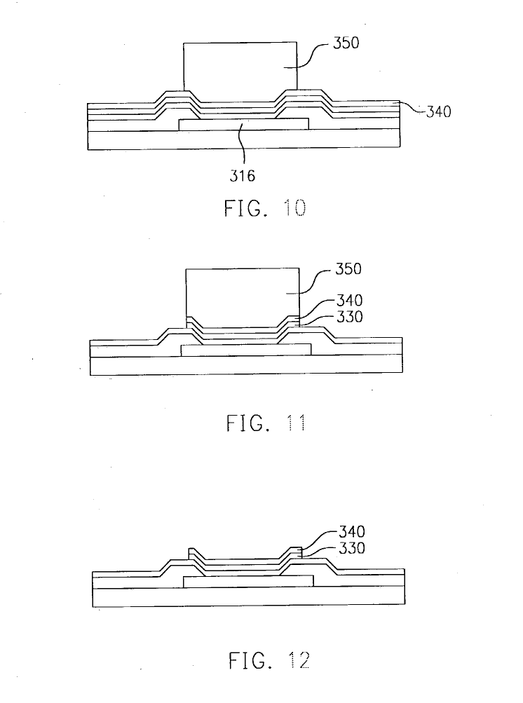

With reference to FIG. 9, an adhesive layer 320 is formed on the active surface 312 of the wafer 310 by sputtering or evaporating. The adhesive layer 320 covers the bonding pad 316 and the passivation layer 314. The material for the adhesive layer 320 is, for example, titanium, titanium-tungsten alloy, aluminum or chromium. A barrier layer 330 is formed over the adhesive layer 320 by sputtering or plating. The material for the barrier layer 330 can be nickel vanadium alloy. A wettable layer 340 is formed over the barrier layer 330 by sputtering, plating or evaporating. The material for the wettable layer 340 can be copper, palladium or gold. Thereby is formed a UBM 342.

With reference to FIG. 10, a first photolithgraphy process is performed. A photoresist layer is formed over the wettable layer 340 by a photolithography process. After exposure and development, the photoresist layer is patterned to include a plurality of patterns 350 (only one is shown) which respectively cover the bonding pads 316.

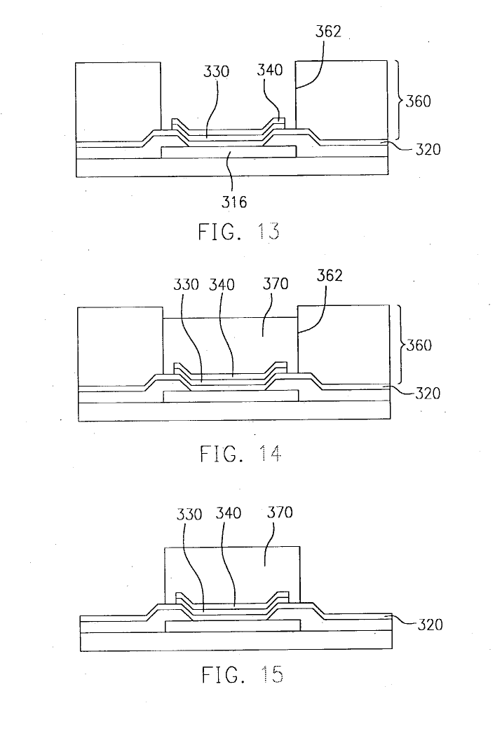

With reference to FIG. 11, a first etching process is performed to remove the portions of wettable layer 340 and barrier layer 330 not covered by the pattern 350. Echants used to etch the wettable layer 340 (made of cooper) can be ammonium hydroxide or hydrogen peroxide. For example, the etchants disclosed in U.S. Pat. No. 6,222,279 are suitable in the invention. Alternatively, the etchant can be K₂ SO₄ or glycerol, as disclosed in U.S. Pat. No. 5,486,282 and U.S. Pat. No. 5,937,320. Other etchants known in the art, for example, sulfuric acid based solution, can be also adequate to etch the wettable layer 340.

In a first embodiment of the invention, 1%-98% sulfuric acid is used to etch the barrier layer 330 at room temperature. When the thickness of the barrier layer 330 is in a range of about 2000 to 4000 angstroms, the etching time is more than 2 hours.

In a second embodiment of the invention, 1%-98% sulfuric acid is used to etch the barrier layer 330 at a temperature of more than 80° C. When the thickness of the barrier layer 330 is in a range of 2000 to 4000 angstroms, the etching time is more than 2 hours.

In a third embodiment of the invention, electrochemically etching is performed by using 10% sulfuric acid with a current density of 0.001-0.02 A/cm², preferably 0.0025 A/cm². When the thickness of the barrier layer 330 is in a range of 2000 to 4000 angstroms, the etching time is about 20 seconds to 110 seconds. Furthermore, a further etching process can be performed by applying a constant current or pulse current.

The barrier layer 330 formed of nickel-vanadium alloy can be etched by diluted phosphoric acid. The composition of the diluted phosphoric acid is, for example, that disclosed in U.S. Pat. No. 5,508,229.

In the above etching process, in order to completely clean the echant on the wafer, de-ionized water is used to rinse the wafer.

With reference to FIG. 12, the pattern 350 is removed.

With reference to FIG. 13, a second etching process is performed. The photoresist layer 360 is formed over the adhesive layer 320 and the wettable layer 340 by a photolithography process. After exposure and development, the photoresist layer 360 is patterned to include a plurality of openings 362 (only one is shown) which respectively expose the wettable layer 340 and a portion of the adhesive layer 320 not covered by the barrier layer 330.

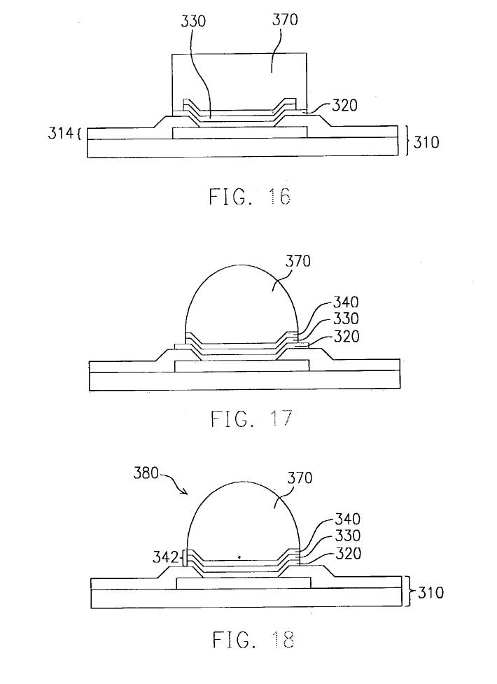

With reference to FIG. 14, a plurality of solders 370 (only one is shown) are respectively formed in the openings 362. The solder 370 covers the wettable layer 340 and the portion of the adhesive layer 320 not covered by the barrier layer 330. The photoresist layer 360 is removed from the adhesive layer 320.

As shown in FIG. 15 and FIG. 16, a second etching process is performed to remove the exposed adhesive layer 320 until the passivation layer 340 is exposed. The etchant used in the second etching process is selected according to the material of the adhesive layer 320.

When the adhesive layer 320 is formed of titanium-tungsten alloy, the etchant to be used can be, for example, hydrogen peroxide (H₂O₂), ethylenediaminetetraacetic (EDTA) and potassium sulphate (K₂SO₄), which are unlikely to erode the solder 370. Alternatively, etchants disclosed in U.S. Pat. No. 5,462,638 can be used.

When the adhesive layer 320 is formed of chromium, the etchant to be used can be, for example, hydrochloric acid (HCl), which also is unlikely to erode the solder 370. Alternatively, etchants disclosed in U.S. Pat. No. 5,162,257 can be used.

When the adhesive layer 320 is formed of titanium, the etchant to be used can be, for example, ammonium hydroxide and hydrogen peroxide (H₂O₂), which also is unlikely to erode the solder 370. Alternatively, etchants disclosed in U.S. Pat. No. 5,162,257 can be used. HF is also suitable as the etchant.

When the adhesive layer 320 is formed of aluminum, the etchant to be used can be, for example, phosphoric acid and acetic acid. Alternatively, etchant disclosed in U.S. Pat. No. 5,508,229 can be used.

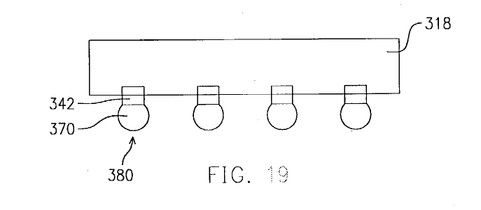

With reference to FIG. 17, a first reflow process is performed. A flux can be optionally distributed over the solder 370 before the solder 370 is heated to help the solder 370 respectively melt into a shape of ball. It is noted that the solder 370 must be not wettable with the adhesive layer 320, so that the solder 370 is constricted on the wettable layer 340 due to the action of cohesion. More specifically, after the first reflow, the solder 370 does not extend to the adhesive layer exposed by the barrier layer 330. A third etching is performed to remove the exposed adhesive layer 320, as shown in FIG. 18. Since the echant erodes the solder 370 during the third etching process, the profile of the solder 370 becomes bumpy. Therefore, a second reflow process can be optionally performed. The flux is distributed over the solder 370 before the solder 370 is subject to a thermal process. Thereby, a bump 380 is accomplished.

After the second etching is finished, the wafer can be diced into a plurality of chips, without the first reflow process, the third etching process and the second reflow process all of which are optional.

As shown in FIG. 8 to FIG. 19, etching the UMB 342 is achieved by three steps. In the first etching step in which the wettable layer 340 and the barrier layer 330 are etched, the solder 370 is not formed on the wettable layer 340 and therefore not eroded by the etchant. In the second and third etching steps in which the adhesive layer 320 is etched, the etchant contacts with and erodes the solder 370. In order to prevent the solder 370 from peeling off the wettable layer 340, the large opening 362 is formed in the photoresist layer 360 to enhance the contact area between the wettable layer 340 and the solder 370. The opening 362 can be of any shape such as circle or polygon. The thickness of the photoresist 360 and thus the production cost are reduced.

The material used to form the UBM is not limited to those recited above. Any material can be also used as long as the adhesive layer is not wettable with the solder.

The material for the solder can be gold, tin lead alloy or nonlead metal. The material for the bonding pad can be aluminum or copper.

The number of the layers constituting the UBM is not limited to three, i.e., the adhesive layer, the barrier layer and the wettable layer. Any number of conductive layers, for example, four conductive layers chrominum/chrominum/copper alloy/copper/silver can be used as the UBM. Alternately, a two-layered structure in which a lower layer is copper layer, nickel layer or gold layer, and an upper layer is titanium/tungsten alloy or titanium can be used as the UBM.

Optionally, a redistribution layer can be optionally formed on the active surface of the wafer before the solder is formed. A method for forming the redistribution layer is well known and thus its description is omitted here.

In a view of above, the invention has a following advantages:

1. Etching the UMB is achieved by three steps. In the first etching step in which the wettable layer and the barrier layer are etched, the solder is not formed on the wettable layer and therefore not eroded by the etchant. In the second and third etching steps in which the adhesive layer is etched, the etchant contacts with and erodes the solder. The time during which the etchant contacts the solder is reduced and therefore the volume of the solder etched off by the etchant is reduced. Furthermore, peeling of the solder can be prevented.

2. In order to prevent the solder from peeling off the wettable layer, the large opening is formed in the photoresist layer to increase the contact area between the wettable layer and the solder. Therefore, the thickness of the photoresist is reduced and the production cost is reduced.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

1. A process for forming a plurality of bumps on a wafer, comprising:
forming a first UBM (under ball metallurgy) over an active surface of the wafer;
forming a second UBM over the first UBM;
performing a photolithography process to form a plurality of patterns on the second UBM;
performing a first etching process to remove a portion of the second UBM not covered by the patterns;
removing the patterns;
performing a second photolithography process to form a photoresist layer over the adhesive layer, wherein the photoresist layer has a plurality of openings respectively exposing portions of the second UBM and the first UBM not covered by the second UBM;
forming a plurality of solders respectively into the openings of the photoresist layer to cover the portions of the second UBM and first UBM not covered by the second UBM;
removing the photoresist layer; and
performing a second etching process to remove the portions of the first UBM respectively not covered by the second UBM and the solders.

2. The process of claim 1, further comprising a step of performing a first reflow process to respectively shape the solders into balls after the second process, wherein the balls are constricted on the second UBM, and the portion of the first UBM not covered by the second UBM is thereby exposed.

3. The process of claim 2, further comprising a step of performing a third etching process to remove the portion of the first UBM not covered by the second UBM after the first reflow process.

4. The process of claim 1, wherein the step of forming a second UBM on the first UBM further includes:
forming a barrier layer over the first UBM; and
forming a wettable layer over the barrier layer.

5. The process of claim 4, wherein the material of the barrier layer is nickel-vanadium alloy.

6. The process of claim 4, wherein the material of the wettable layer is selected from a group consisting of copper, palladium and gold.

7. The process of claim 1, wherein the first UBM is an adhesive layer that is made of a material selected from a group consisting of titanium, titanium tungsten alloy, aluminum and chromium.

8. The process of claim 5, wherein an etchant used to etch the barrier layer in the first etching step includes sulfuric acid.

9. The process of claim 8, wherein 1%-98% sulfuric acid is used to etch the barrier layer having a thickness of about 2000 to 4000 angstroms at room temperature for more than 2 hours.

10. The process of claim 8, wherein 1%-98% sulfuric acid is used to etch the barrier layer having a thickness of about 2000 to 4000 angstroms at a temperature of more than 80° C. for more than 2 hours.

11. The process of claim 8, wherein 10% sulfuric acid is used with a current density of about 0.001 to 0.02 A/cm to etch the barrier layer having a thickness of about 2000 to 4000 angstroms at a temperature of more than 80° C. for about 20 seconds to 110 seconds.

12. The process of claim 15, wherein an etchant used to etch the barrier layer in the first etching step includes a diluted phosphoric acid.

13. The process of claim 1, wherein the solder is not wettable with the first UBM.

14. A process for forming a plurality of bumps on a wafer, the process comprising:
1) forming a first UBM (under ball metallurgy) over an active surface of the wafer;
2) forming a second UBM over the first UBM;
3) removing a portion of the second UBM to expose the first UBM;
4) forming a plurality of solders correspondingly on the second UBM and a portion of the first UBM not covered by the second UBM; and
5) removing the portion of the first UBM respectively not covered by the second UBM and the solders.

15. The process of claim 14, further comprising a step of performing a first reflow process to respectively shape the solder into balls after step 5), wherein the balls are constricted on the second UBM, and the portion of the first UBM not covered by the second UBM is thereby exposed.

16. The process of claim 15, after the first reflow process, further comprising a step of removing the first UBM not covered by the second UBM after the first reflow.

17. The process of claim 15, further comprising a second reflow process after step 5).

18. The process of claim 14, wherein the step 2) further includes:
forming a barrier layer over the first UBM; and
forming a wettable over the barrier layer.

19. The process of claim 18, wherein the material of the barrier layer is nickel-vanadium alloy.

20. The process of claim 19, wherein an etchant used to etch the barrier layer in the first etching step includes sulfuric acid.

21. The process of claim 20, wherein 1%-98% sulfuric acid is used to etch the barrier layer having a thickness of about 2000 to 4000 angstroms at room temperature for more than 2 hours.

22. The process of claim 20, wherein 1%-98% sulfuric acid is used to etch the barrier layer having a thickness of about 2000 to 4000 angstroms at a temperature of more than 80° C. for more than 2 hours.

23. The process of claim 20, wherein 10% sulfuric acid is used with a current density of about 0.001 to 0.02 A/cm to etch the barrier layer having a thickness of about 2000 to 4000 angstroms at a temperature of more than 80° C. for about 20 seconds to 110 seconds.

24. The process of claim 19, wherein an etchant used in step 3) is a diluted phosphoric acid.

25. The process of claim 18, wherein the material of the wettable layer is selected from a group consisting of copper, palladium and gold.

26. The process of claim 25, wherein an echant used to etch the wettable layer made of cooper includes ammonium hydroxide and hydrogen peroxide.

27. The process of claim 25, wherein an echant used to etch the wettable layer made of cooper includes potassium sulfate and glycerol.

28. The process of claim 14, wherein the first UBM is an adhesive layer that is made of a material selected from a group consisting of titanium, titanium tungsten alloy, aluminum and chromium.

29. The process of claim 28, wherein when the adhesive layer is made of titanium-tungsten alloy, an etchant used to etch the adhesive layer contains hydrogen peroxide (H₂O₂), ethylenediaminetetraacetic (EDTA) and potassium sulphate (K₂SO₄).

30. The process of claim 28, wherein when the adhesive layer is made of chromium, an etchant used to etch the adhesive layer includes hydrochloric acid (HCl).

31. The process of claim 28, wherein when the adhesive layer is made of titanium, an etchant used to etch the adhesive layer includes ammonium hydroxide and hydrogen peroxide (H₂O₂).

32. The process of claim 28, wherein, which when the adhesive layer is made of titanium, an etchant used to etch the adhesive layer includes HF.

33. The process of claim 28, wherein when the adhesive layer is made of aluminum, an etchant used to etch the adhesive layer includes phosphoric acid and acetic acid.

34. The process of claim 14, wherein the solder is not wettable with the first UBM.
